(19) United States
(12) Patent Application Publication
(10) Pub. No.: US 2015/0208551 A1
(43) Pub. Date: Jul. 23, 2015

(54) Apparatuses for Transmitting Heat Between a Rail of Rack Mounted Equipment and a Channel of a Cooling Rack Enclosure, And Related Components, Systems, and Methods

(71) Applicant: ADC Technologies Inc., Montreal (CA)

(72) Inventor: Niall Thomas Davidson, Hamilton (GB)

(21) Appl. No.: 14/422,551

(22) PCT Filed: Aug. 19, 2013
(86) PCT No.: PCT/IB2013/001789

§ 371 Date: Feb. 19, 2015

Related U.S. Application Data
(60) Provisional application No. 61/684,856, filed on Aug. 20, 2012.

(51) Int. Cl. H05K 7/20

(52) U.S. Cl. CPC H05K 7/20663

(57) ABSTRACT

Rack mountable equipment and a complementary cooling rack enclosure are arranged to work together to transmit heat from heat generating components of the rack mountable equipment to the cooling rack enclosure. Heat from the components is transferred to the cooling rack enclosure via a coolable surface disposed in a channel of the cooling rack enclosure. The rack mountable equipment includes a rail adapted to be received by the channel in the cooling rack enclosure. A thermally conductive surface on the rail contacts the coolable surface within the channel and transfers heat from the rack mountable equipment to the cooling rack enclosure.

### PRIORITY APPLICATION

The present application claims priority to U.S. Patent Application Ser. No. 61/684,856 filed on Aug. 20, 2012 entitled “Cooling Electronic Equipment in a Rack Enclosure,” which is incorporated herein by reference in its entirety.

### BACKGROUND

Electronic equipment generates a large amount of unwanted heat, and efficiently dissipating or recycling this unwanted heat within data centers is a major concern.

Several methods for managing this unwanted heat can be used. These methods include cooling or removing hot air exhausted from electronic equipment, liquid cooling heat generating components within equipment, and even immersing equipment into liquid coolants.

Each method has its drawbacks. Exhausting hot air from electronic equipment can require that the hot air is removed using some form of heating, ventilation and air conditioning (HVAC) system and replaced with fresh air. Exhausting hot air can alternatively require that the hot air is cooled and recycled within the data center, frequently involving the use of water chillers. This requires additional energy and equipment and introduces multiple points of failure. Liquid cooling meanwhile, while effective, can make maintenance and upgrades complex and introduces a risk of leakage within sensitive environments.

A need therefore exists to remove heat from electronic equipment deployed in data centers in an efficient manner which is low risk and versatile.

### SUMMARY

Embodiments include rack mountable equipment and a complementary cooling rack enclosure arranged to work together to transmit heat from heat generating components of the rack mountable equipment to the cooling rack enclosure. Heat from the components is transferred to the cooling rack enclosure via a coolable surface disposed in a channel of the cooling rack enclosure. The rack mountable equipment includes a rail adapted to be received by the channel in the cooling rack enclosure. A thermally conductive surface on the rail contacts the coolable surface within the channel and transfers heat from the rack mountable equipment to the cooling rack enclosure. The disclosed enclosure may be backwards compatible with existing equipment, such as standard fan cooled rack mounted equipment. One benefit of this arrangement is that, by using a structural support connection between the rail and channel as the heat transmitting mechanism, the force of gravity may be sufficient to maintain contact between the thermally conductive surface of the installed equipment and a cooled surface of the enclosure.

One exemplary embodiment discloses a rack mountable equipment of a type which can be cooled by installation into a cooling rack enclosure. The equipment comprises a heat generating component and heat transmitter. The equipment further comprises a rail adapted to be received by a channel in an enclosure when the equipment is installed in the enclosure. The equipment further comprises a thermally conductive surface located on the rail, the thermally conductive surface thermally connected via the heat transmitter to the heat generating component.

Another exemplary embodiment discloses a rack enclosure into which rack mounted equipment can be installed. The rack mounted equipment is of a type which can be cooled by installation into a cooling rack enclosure. The rack mounted equipment further comprises a rail comprising a thermally conductive surface. The rack enclosure comprises a channel adapted to receive the rail of the rack mounted equipment when the equipment is installed into the enclosure. The rack enclosure further comprises a coolable surface disposed on a surface of the channel in such a way that the coolable surface is adjacently located to the thermally conductive surface when the equipment is installed into the enclosure.

In another embodiment, a method of cooling rack mounted equipment is disclosed. The method comprises enabling the transmission of heat from a heat-generating component of the rack mounted equipment to a thermally conductive surface. The method further comprises configuring the thermally conductive surface such that it can be urged against a cooled surface of a cooling apparatus by using a magnetic fastener.

In another embodiment, a method of cooling rack mounted equipment is disclosed. The method comprises enabling the transmission of heat from a heat-generating component of the rack mounted equipment to a thermally conductive surface. The method further comprises configuring the thermally conductive surface such that it can be urged against a cooled surface of a cooling apparatus by using a magnetic fastener.

In another embodiment, a method of cooling rack mounted equipment is disclosed. The method comprises positioning a magnetically attractive feature such that a thermally conductive surface can be urged against a cooled surface by a magnetic fastener cooperating with the magnetically attractive feature.

In another embodiment, a cooling apparatus for cooling a thermally conductive surface of rack mountable equipment is disclosed. The cooling apparatus comprises a heat-generating component thermally connected to a thermally conductive surface. The cooling apparatus comprises a coolable surface and a magnetically attractive feature configured such that a magnetic fastener can be used to urge the thermally conductive surface against the cooled surface.

In another embodiment, an apparatus is disclosed. The apparatus comprises a heat-generating component, a heat transmitter, and a thermal connector. The thermal connector comprises a thermally conductive surface. The thermally conductive surface is thermally connected to the heat-generating component by the heat transmitting means. The thermal connector is configured to be urged against a surface by a magnetic fastener.

### DRAWINGS

These and other features, aspects, and advantages of embodiments of the present disclosure will become better understood with regard to the following description, appended claims, and accompanying drawings where:

FIGS. 1 and 2 show views of an exemplary thermal connector designed to be urged against a counterpart surface by a magnetic fastener;

FIG. 3 shows an exemplary computer system with the thermal connector of FIG. 1, the computer system of a type suitable for installation in a shelf-style rack enclosure;

FIG. 4 shows an exploded view of an exemplary liquid cooled apparatus designed to operate with the thermal connector of FIG. 1;

FIG. 5 shows an end view of the apparatus of FIG. 4;

FIG. 6 shows a view of an exemplary magnetic fastener suitable for use with the thermal connector of FIG. 1;

FIG. 7 illustrates the magnetic fastener of FIG. 6 being used to urge a thermal connector against a magnetically attractive surface;

FIG. 8 shows the apparatus of FIG. 4 integrated with a shelf-style rack enclosure and the computer system of FIG. 3 installed therein;

FIGS. 9 and 10 show views of an exemplary thermal connector designed to be received by an aperture of a cooling apparatus;

FIG. 11 shows an exemplary dual processor computer system with the thermal connector of FIGS. 9 and 10, the computer system of a type suitable for installation in a shelf-style rack enclosure;

FIG. 12 shows an exemplary flat spring insert suitable for urging the thermal connector of FIGS. 9 and 10 against the cooled surface of a cooling apparatus;

FIGS. 13 and 14 show the computer system of FIG. 11 installed in a shelf-style rack enclosure incorporating apertures configured to receive the thermal connector of FIGS. 9 and 10;

FIG. 15 shows an exemplary computer system in a 3U enclosure with a pair of thermal connector rails which are configured to be received by apertures in a rack enclosure; and

FIGS. 16 and 17 show the computer system of FIG. 15 installed in a rack enclosure, the rack enclosure having apertures configured to receive and cool the thermal connector rails.

### DETAILED DESCRIPTION

Embodiments include rack mountable equipment and a complementary cooling rack enclosure arranged to work together to transmit heat from heat generating components of the rack mountable equipment to the cooling rack enclosure. Heat from the components is transferred to the cooling rack enclosure via a coolable surface disposed in a channel of the cooling rack enclosure. The rack mountable equipment includes a rail adapted to be received by the channel in the cooling rack enclosure. A thermally conductive surface on the rail contacts the coolable surface within the channel and transfers heat from the rack mountable equipment to the cooling rack enclosure. The disclosed enclosure may be backwards compatible with existing equipment, such as standard fan cooled rack mounted equipment. One benefit of this arrangement is that, by using a structural support connection between the rail and channel as the heat transmitting mechanism, the force of gravity may be sufficient to maintain contact between the thermally conductive surface of the installed equipment and a cooled surface of the enclosure.

It is intended that the following description and claims should be interpreted in accordance with Webster's Third New International Dictionary, Unabridged unless otherwise indicated.

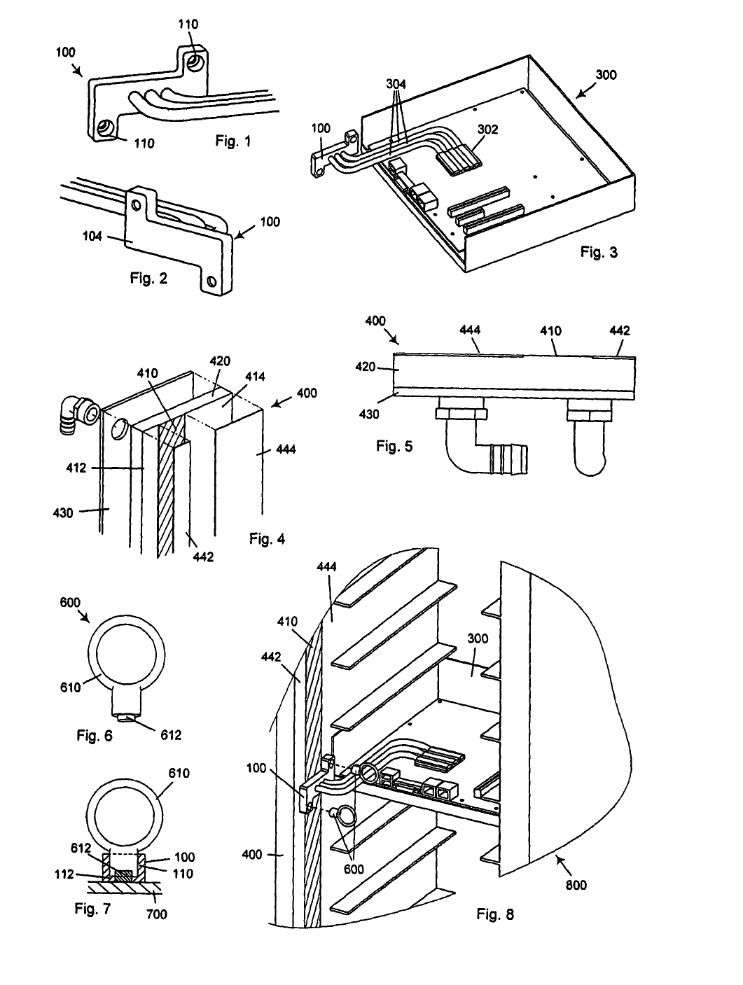

In the following specification and claims, a “thermal connector” is defined to be an apparatus, article of manufacture or portion of an apparatus or article of manufacture, the purpose of which is to transfer, transmit or communicate heat to a counterpart thermal connector when contacted with or otherwise interacting with the counterpart thermal connector. Examples of thermal connectors are shown in FIGS. 1, 2, 9, 10 and 15. It is not intended that the definition of a thermal connector be limited to the shape and form of the examples shown and described, nor that they are limited to operating via physical contact; nor is it necessary that a thermal connector is distinct. A thermal connector may, for instance, be a portion of a surface of an enclosure which is brought into contact with a counterpart surface to transfer, transmit or communicate heat. A person having ordinary skill in the art will be able to devise numerous and diverse thermal connectors which can be used by apparatuses embodying features of embodiments of the present disclosure.

It is intended that a “thermal connector” as defined above is interpreted to include a surface which is configured, adapted, or otherwise intended to be contacted by another surface for the purpose of communicating heat between the surfaces.

In the following specification and claims, a “heat transmitting means” is intended to encompass heatpipes, vapor chambers, thermosyphons, thermal interface materials, and thermally conductive materials, composites, manufactures and apparatus such as: thermally conductive metals, examples of which include copper, aluminium, beryllium, silver, gold, nickel and alloys thereof; thermally conductive non-metallic materials, examples of which include diamond, carbon fiber, carbon nanotubes, graphene, graphite and combinations thereof; composite materials and manufactures, examples of which include graphite fiber/copper matrix composites and encapsulated graphite systems; and apparatuses such as liquid circulation, heat pumps and heat exchangers. A “heat transmitting means” is further intended to encompass any means presently existing or that is discovered in the future which transmits heat from one place to another.

Apparatuses for cooling shelf-style rack mounted equipment using a thermal connector and magnetic fasteners are disclosed. The apparatus comprises a thermally conductive surface thermally connected to a heat generating component such as a computer processing unit (CPU) via a heat transmitter such as a heatpipe. The thermally conductive surface is configured to be urged against a cooled surface by a magnetic fastener when the equipment is installed.

FIGS. 1 and 2 show a thermal connector 100 which is designed to be held against a cooled surface by magnetic fasteners. The thermal connector 100 comprises a thermally conductive surface 104 which can be contacted to a cooled surface to enable heat communication, and apertures 110 into which magnetic fasteners are inserted to urge the thermal connector against a surface. The thermal connector 100 has a thermally conductive surface manufactured from a thermally conductive material.

FIG. 3 illustrates the thermal connector of FIGS. 1 and 2 thermally connected via a heat transmitting means to a heat-generating component of a computer system 300 in a tray type chassis suitable for installation in a shelf-style rack enclosure. The thermally conductive surface 104 of the thermal connector 100 is thermally connected via a plurality of heat pipes 304 to a CPU 302, when in operation. Heat generated by the CPU is transmitted via the heat pipes 304 to the thermally conductive surface 104. By cooling the thermally conductive surface 104, the CPU 302 can be maintained within thermal parameters. In some embodiments, using flexible heatpipes (bellows type or other) may allow the thermally conductive surface 104 to be more easily urged against a counterpart surface.

FIG. 4 shows an exploded view of one end of an apparatus 400 designed to cool the thermally conductive surface 104. The apparatus 400 comprises a part 420 comprising a thermally conductive surface 410 and recessed surfaces 412 and 414, which are parallel to and recessed below the surface 410. Plates 442 and 444 are made from a magnetically attractive material. The plates are configured to fit into the recessed surfaces 412 and 414 such that the surface 410 and surfaces 412 of the plates 442 and 444 form a uniform surface. A lid 430 is provided as a seal from the outside environment.

FIG. 5 shows a view from one end of the assembled apparatus 400, and illustrates the uniform surface created by surface 410 and plates 442 and 444. The uniform surface is configured to be contacted by one or more thermal connectors of the type shown in FIGS. 1 and 2. While the example described attempts to provide a uniform surface, alternate configurations of both thermal connector and cooling apparatus surfaces, including, for example, non-uniform surfaces, can be devised which do not depart from the scope and spirit of embodiments of the present disclosure.

The recessed surfaces 412 and 414 of the part 420 are configured such that a thermal connector 100, which has apertures 110 a certain distance apart, can be fastened by a magnetic fastening means 600 to the magnetically attractive plates 442 and 444 while maximizing contact with the surface 410. The magnetically attractive plates are fastened to the part 420 by means of an adhesive or other fastening means such as screws. Optionally, the use of a thermal adhesive can improve heat conduction between thermal connectors contacting the magnetically attractive plate and the part 420. Alternatives to the magnetically attractive plates of apparatus 400 include constructing the cooling apparatus entirely from magnetically attractive materials or providing magnetically attractive features positioned only where required to provide fastening points.

The part 420 has a series of channels beneath the surface 410 which are configured such that a liquid coolant can flow beneath and cool any thermal connectors contacted to the surface 410. In this embodiment, the channels are sealed from the outside environment by the lid 430. In some embodiments, configuring the channels such that coolant flows in parallel beneath thermal connectors will allow each thermal connector being cooled to be cooled independently of others.

FIG. 6 illustrates a magnetic fastener 600 suitable for use with the thermal connector 100 and apparatus 400. The magnetic fastener 600 comprises a magnet 612 and body 610 designed to aid removal. The use of the magnetic fastener 600 is illustrated by FIG. 7, which shows a magnetic fastener 600 being used to urge a thermal connector 100 against a magnetically attractive material 700. The magnetic fastener 600 is inserted into the aperture 110 of the thermal connector 100. The aperture 110 comprises a shelf 112 which allows the magnet 612 of the magnetic fastener 600 to pass through and be brought into proximity to the surface 700 while the body 610 of the magnetic fastener is brought into contact with the shelf 112. The force developed between the magnet 612 and the surface 700 urges the thermal connector 100 against the surface 700.

FIG. 8 shows an example of the apparatus 400 integrated with a shelf-style rack enclosure 800. The computer system 300 is shown installed with the thermal connector 100 contacted to the apparatus 400 and urged against the surface 410 by magnetic fasteners 600. FIG. 8 illustrates how the magnetically attractive plates 442 and 444 are positioned to allow the thermal connector 100 to be urged against the surface by magnetic fasteners 600 while contacting a large area of surface 410 with the thermally conductive surface 104 of the thermal connector 100.

Other toolless fasteners that may be used in place of magnetic fasteners include, but are not limited to, latches, thumbscrews, and non-screw rotating fasteners which fasten and generate a pulling force along the axis of rotation.

Another apparatus for cooling shelf-style rack mounted equipment is disclosed, the apparatus comprising a thermal connector which is thermally connected to a heat generating component via a heat transmitting means such as a heatpipe. The thermal connector is configured to be received by an aperture in a cooling apparatus when the equipment is installed.

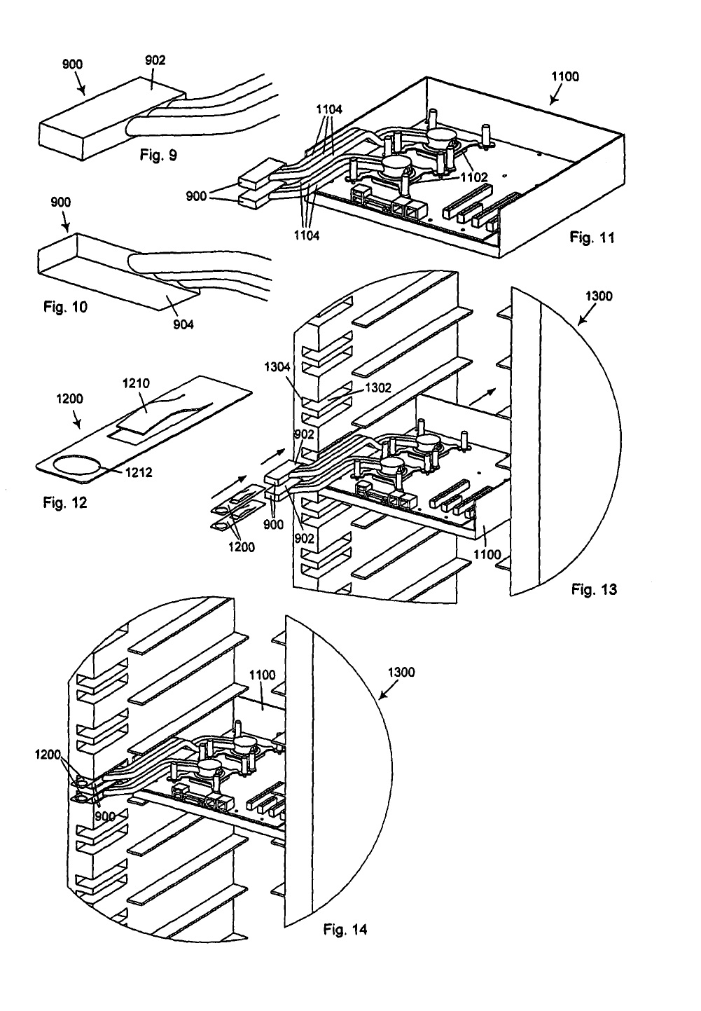

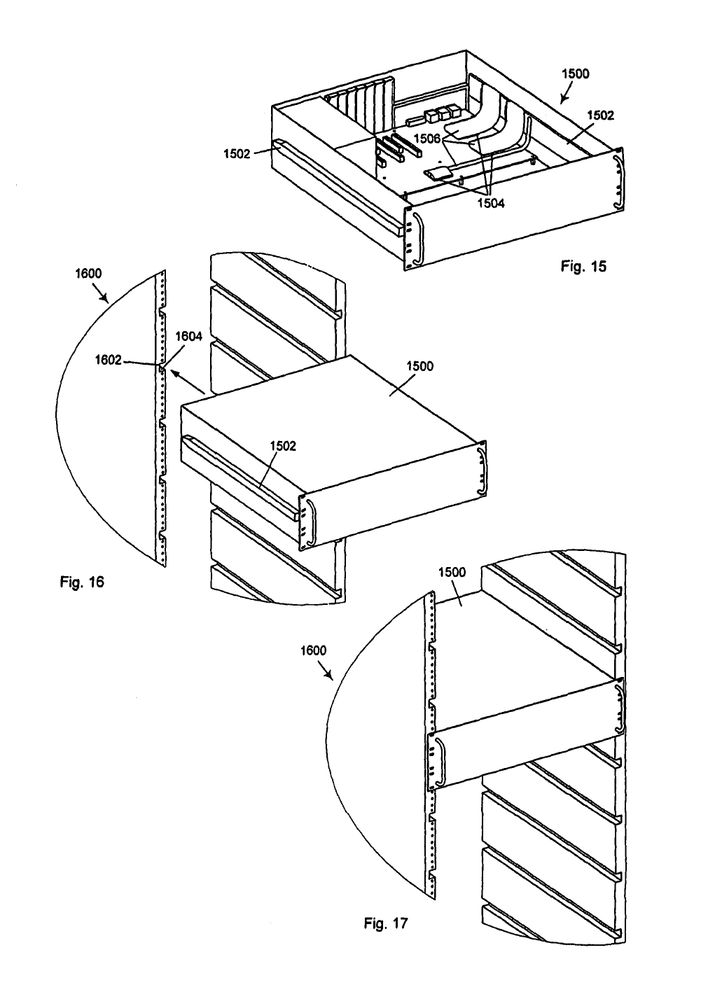

FIGS. 9 and 10 illustrate a thermal connector 900 which is configured to be received by an aperture in a cooling apparatus, FIG. 9 shows a view of the top surface 902 and FIG. 10 shows a view of the bottom surface 904 which is thermally conductive. For the example illustrated by FIGS. 9 and 19, each surface 902 and 904 is a flat surface and is designed to cooperate with the cooling apparatus such that, when the thermal connector 900 is positioned within the aperture of the cooling apparatus, the surface 904 can be urged against a flat counterpart surface of the cooling apparatus by a flat spring, which is inserted between the top surface 902 and a surface of the cooling apparatus. This functionality is further illustrated in FIGS. 13 and 14, discussed below.

Alternatives to the thermal connector 900 and cooling apparatus described include, but are not limited to, using other profiles for the contacting surfaces or using alternative urging means. One example includes configuring a part of the cooling apparatus such that it can be moved to clamp a thermal connector against a counterpart surface. Another example includes configuring a part of the thermal connector such that it can be moved to urge a surface of the thermal connector against a surface of the counterpart cooling apparatus. Another example includes configuring the cooling apparatus and thermal connector such that the thermal connector comprises one or more heatpipes, which are received by a profiled surface of the cooling apparatus such that each heatpipe can be clamped by a movable part of the cooling apparatus.

FIG. 11 illustrates a dual processor computer system 1100 in a tray type chassis suitable for installation in a shelf-style rack enclosure. The computer system 1100 comprises thermal connectors 900 thermally connected to each CPU 1102 via a plurality of heatpipes 1104.

FIG. 12 illustrates a flat spring insert 1200. The insert comprises a spring portion 1210 and an opening 1212 which aids with removal and insertion of the insert.

FIGS. 13 and 14 show a shelf-style rack enclosure 1300 with a plurality of apertures 1304 configured to receive one or more thermal connectors 900. Each aperture 1304 comprises a cooled surface 1302 against which a thermal connector 900 can be urged by a means such as spring insert 1200. FIG. 13 illustrates the computer system 1100 being installed in a shelf. Each thermal connector 900 of the computer system 1100 aligns with an aperture 1304 of the enclosure 1300.

FIG. 14 shows the computer system 1100 in its installed position in the shelf-style rack enclosure. Each thermal connector 900 is received by an aperture 1304 and the surfaces 904 are urged against the cooled surfaces 1302 by spring inserts 1200.

The cooled surface 1302 of each aperture 1304 of the enclosure 1300 may be cooled by any cooling means. One example of achieving cooling is to pass a liquid coolant beneath each cooled surface 1302. In this way, heat can be removed from the thermal connectors 900 being urged against the surface 1302 in an efficient manner and transported for later dissipation. This yields the benefit of liquid cooling with a significantly reduced risk of leak, and does not create significant difficulties with respect to maintaining or replacing equipment installed in the enclosure.

In another embodiment, another apparatus for cooling rack mounted equipment is disclosed. The apparatus comprises a pair of rail thermal connectors which are thermally connected to one or more heat generating components via a heat transmitting means, such as a heatpipe. In this embodiment, the rail thermal connectors are configured to be received by an aperture in a cooling apparatus when the equipment is installed, and optionally support some or all of the weight of the equipment.

FIG. 15 illustrates a computer system 1500 in a 3U enclosure. The computer system 1500 comprises a pair of rail thermal connectors 1502, one on each side of the enclosure, to which a plurality of heat generating components 1504 are thermally connected by heat transmitting means in the form of heatpipes 1506. The rail thermal connectors 1502 have a thermally conductive surface on at least the surface of the rail which is to be urged or braced against a cooled surface. The heat generating components 1504 are thermally connected to this surface by the heat transmitting means.

FIG. 16 shows the computer system 1500 being installed in a rack enclosure 1600. The rack enclosure 1600 has a plurality of apertures 1602, e.g., U-shaped channels, which are designed to receive the rail thermal connectors 1502. Each aperture 1602 comprises a cooled surface 1604. FIG. 17 shows the computer system 1500 installed in the rack enclosure 1600. The weight of the computer system 1500 urges the rail thermal connector 1502 against the surface 1604. Additional force may be applied if the weight is not sufficient to create an adequate thermal connection, or if the rail is not intended to support weight. For example, an apparatus may be used which allows for the rail thermal connector to be urged against the surface 1604 by turning a handle or pulling/pushing a lever to move a part and urge the thermally conductive surface of the rail against the surface 1604. The cooled surface 1604 can be cooled in a fashion similar to that of surface 1302 described above. The rack enclosure 1600 of FIGS. 16 and 17 offers an advantage that both legacy equipment and equipment with rail thermal connectors can be installed in the same rack enclosure without interfering with the operation of the other type.

The above embodiments have a number of advantages. For example, quick and easy installation of equipment into a rack enclosure is enabled, with no complex fittings or fasteners needed during installation. Another advantage of the above embodiments is that an urging force can urge the thermally conductive surface of installed equipment against the cooled surface of the enclosure without inducing stress or strain in the body of the installed equipment. Instead, in many embodiment, the only force against the equipment is maintained as a clamping action operating on the thermal connector while avoiding putting significant stress or strain on the body of the installed equipment.

In addition, by disposing heat exchanging surfaces on both the equipment and the enclosure as disclosed, non-flexible heat transmitting means, e.g. fixed heat pipes, can be used to transmit heat to both sides of the equipment. Additionally, as disclosed in one embodiment above, the force of gravity may be sufficient to maintain contact between the thermally conductive surface of the installed equipment and a cooled surface of the enclosure.

While some of the examples described disclose thermal connectors which are similarly positioned relative to the example computer systems, it is not intended that apparatuses embodying principles of the present disclosure are required to have such positioning. Further, it is not intended that the teachings of the present disclosure are limited to computer systems, a specific form of enclosure, or a specific type of heat-generating component, and it is expected that principles of the present disclosure can be applied to other forms of apparatus.

Although specific embodiments of the disclosure have been shown and described herein, it is to be understood that these embodiments are merely illustrative of the many possible specific arrangements that can be devised in application of the principles of the disclosure. Numerous and varied other arrangements can be devised by those of ordinary skill in the art without departing from the scope and spirit of the disclosure.

1. Rack mountable equipment of a type which can be cooled by installation into a cooling rack enclosure, the equipment comprising:
a. a heat generating component;
b. a heat transmitter;
c. a rail adapted to be received by a channel in an enclosure when the equipment is installed in the enclosure, and;
d. a thermally conductive surface located on the rail, the thermally conductive surface thermally connected via the heat transmitter to the heat generating component.

2. The rack mountable equipment of claim 1, wherein the channel is U-shaped.

3. The rack mountable equipment of claim 2, wherein the thermally conductive surface is located such that when the equipment is installed gravity urges a portion of the thermally conductive surface sufficient for the purpose of cooling the equipment against a coolable surface of the channel.

4. The rack mountable equipment of claim 2, wherein the thermally conductive surface is located such that when installed a portion of the thermally conductive surface sufficient for the purpose of cooling the equipment can be urged against a coolable surface of the channel by bracing the rail against an opposing surface of the channel.

5. The rack mountable equipment of claim 1, wherein the thermally conductive surface is located on the rail such that when the equipment is installed gravity urges a portion of the thermally conductive surface sufficient for the purpose of cooling the equipment against a coolable surface of the channel.

6. The rack mountable equipment of claim 1, wherein the thermally conductive surface is located on the rail such that when installed the thermally conductive surface can be urged against a coolable surface of the channel by being braced against a feature of the enclosure.

7. The rack mountable equipment of claim 1, wherein the thermally conductive surface is located such that when installed the thermally conductive surface can be urged against a coolable surface of the channel by bracing the rail against an opposing surface of the channel.

8. The rack mountable equipment of claim 1, wherein the rail projects from a side of the enclosure.

9. The rack mountable equipment of claim 1, further comprising a second rail adapted to be received by a second channel in the enclosure when the equipment is installed, the second rail being located on an opposite side of the equipment that the first rail is located on.

10. The rack mountable equipment of claim 9, wherein a second thermally conductive surface is located on the second rail.

11. A cooling rack enclosure into which rack mounted equipment can be installed, the rack mounted equipment being of a type which can be cooled by installation into a cooling rack enclosure and which comprises a rail comprising a thermally conductive surface, the rack enclosure comprising:
a. a channel adapted to receive the rail of the rack mounted equipment when the equipment is installed into the enclosure, and;
b. a coolable surface disposed on a surface of the channel in such a way that the coolable surface is adjacently located to the thermally conductive surface when the equipment is installed into the enclosure.

12. The rack enclosure of claim 11, wherein the channel is U-shaped.

13. The rack enclosure of claim 12, wherein the coolable surface is disposed such that when the rack mounted equipment is installed gravity urges a portion of the thermally conductive surface sufficient for the purpose of cooling the equipment against the coolable surface.

14. The rack enclosure of claim 12, wherein the coolable surface is disposed such that when the rack mounted equipment is installed a portion of the thermally conductive surface sufficient for the purpose of cooling the equipment can be urged against the coolable surface by bracing the rail against an opposing surface of the channel.

15. The rack enclosure of claim 11, wherein the coolable surface is disposed such that when the rack mounted equipment is installed gravity urges a portion of the thermally conductive surface sufficient for the purpose of cooling the equipment against the coolable surface.

16. The rack enclosure of claim 11, wherein the coolable surface is disposed such that when the rack mounted equipment is installed a portion of the thermally conductive surface sufficient for the purpose of cooling the equipment can be urged against the coolable surface by bracing the rail against a feature of the enclosure.

17. The rack enclosure of claim 11, wherein the coolable surface can be cooled by engendering a flow of a liquid coolant within the rack enclosure.

18. The rack enclosure of claim 11, wherein installed equipment is sufficiently supported by the rail interacting with the channel.

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)
